(19) United States
(12) Patent Application Publication
(10) Pub. No.: US 2018/0188303 A1
(43) Pub. Date: Jul. 5, 2018

(54) GIGAHERTZ TRANSVERSE ELECTROMAGNETIC (GTEM) CELL FOR MEASURING INSERTION LOSS AND INSERTION LOSS MEASUREMENT METHOD USING THE GTEM CELL

(71) Applicant: Electronics and Telecommunications Research Institute, Daejeon (KR)

(72) Inventors: Jung Hwan HWANG, Daejeon (KR); JONG HWA KWON, Daejeon (KR)

(73) Assignee: Electronics and Telecommunications Research Institute, Daejeon (KR)

(21) Appl. No.: 15/484,266

(22) Filed: Apr. 11, 2017

(30) Foreign Application Priority Data
Jan. 2, 2017 (KR) 10-2017-0000161

(51) Int. Cl. G01R 29/08; H01P 3/06; H01P 5/08; H01P 1/26; G01R 27/28

(52) U.S. Cl. CPC G01R 29/0828; H01P 3/06; G01R 27/28; H01P 1/268; H01P 5/085

(57) ABSTRACT

Provided is a gigahertz transverse electromagnetic (GTEM) cell for measuring an insertion loss and an insertion loss measurement method using the GTEM cell. The GTEM cell may include an output port configured to measure an insertion loss of a test object occurring when an electromagnetic field having specific intensity is applied to the test object, and may measure the insertion loss of the test object from the GTEM cell based on a change in the intensity of the electromagnetic field measured using the output port.

### CROSS-REFERENCE TO RELATED APPLICATION(S)

This application claims the priority benefit of Korean Patent Application No. 10-2017-0000161 filed on Jan. 2, 2017, in the Korean Intellectual Property Office, the disclosure of which is incorporated herein by reference for all purposes.

### BACKGROUND

### 1. Field

One or more example embodiments relate to a gigahertz transverse electromagnetic (GTEM) cell for measuring an insertion loss and an insertion loss measurement method using the GTEM cell, and more particularly, to a device for measuring an insertion loss of a test object when an electromagnetic field having specific intensity is applied to the test object and a method of measuring the insertion loss using the device.

### 2. Description of Related Art

In general, an electromagnetic wave measurement device refers to a device designed to form an electromagnetic field having a travelling wave property and also having specific intensity and polarization, and to apply the formed electromagnetic field to a test object. Accordingly, the electromagnetic wave measurement device is used for various tests and measurements in an electromagnetic wave field, such as electromagnetic interference (EMI) and electromagnetic susceptibility (EMS), and includes, as a representative example, an electromagnetic wave semi-anechoic chamber.

The electromagnetic wave semi-anechoic chamber includes an electromagnetic wave blocking architecture configured to block external electromagnetic noise and an electromagnetic wave absorber configured to remove a reflection phenomenon of a travelling wave occurring on a remaining wall surface excluding a bottom surface. The electromagnetic wave semi-anechoic chamber may perform an accurate measurement with respect to a test object, whereas a relatively large space is required due to a large volume of a measurement device. Instead of the electromagnetic wave semi-anechoic chamber, a small measurement device in a form of a waveguide is used to form an electromagnetic field of a travelling wave.

Examples of the measurement device include a transverse electromagnetic (TEM) cell and a gigahertz transverse electromagnetic (GTEM) cell. The TEM cell includes an inner conductor and an outer conductor and is in a spherical coaxial transmission line shape. A test area for placing a test object is present inside the TEM cell. Due to the spherical coaxial transmission line shape, intensity of an electromagnetic field distributed on the test area is very uniform and an accurate test and measurement associated with the test object may be performed. However, an upper limit frequency band is determined based on a physical size of the outer conductor. In a frequency band beyond the upper limit frequency band, the uniformity of the electromagnetic field on the test area may be degraded due to a high order mode. Accordingly, the measurement may not be performed.

The GTEM cell is proposed to outperform the issue that the frequency band measured by the TEM cell is limited. The GTEM cell is provided in a spherical coaxial transmission line, which is similar to the TEM cell, and includes only an input port instead of including a separate output port since one surface of the GTEM cell is open. That is, the GTEM cell is in a single port structure.

Since the output port is not provided, an electromagnetic field and current may extinguish by way of an electromagnetic wave absorber and a load resistance in the GTEM cell once they reach a termination structure and accordingly, a change in the electromagnetic field and the current after passing through the test object may not be measured. Due to such a characteristic by the single port structure, measurement items of the test object may be limited. A typical measurement item to be limited may be an insertion loss occurring when the electromagnetic field passes through the test object.

When a lossy dielectric material is present in a test area of the GTEM cell, the electromagnetic field of a travelling wave form may pass through the dielectric material. Here, a loss component of the dielectric material may reduce intensity of the passing electromagnetic field. The insertion loss, which is a very important variable indicating an electrical characteristic of the dielectric material, refers to a physical quantity indicating a reduced amount of the intensity of the electromagnetic field. However, due to the single port structure, the GTEM cell may not measure the insertion loss.

### SUMMARY

Example embodiments provide a gigahertz transverse electromagnetic (GTEM) cell that may measure an insertion loss of a test object when the test object is a lossy dielectric material.

Example embodiments provide a GTEM cell that may measure a change in intensity of an electromagnetic field when an electromagnetic field formed in the GTEM cell passes through a test object placed on a test area, using an output port provided to the GTEM cell.

Example embodiments provide a GTEM cell that may measure an insertion loss of a test object using a GTEM cell, in which a change in the intensity of the electromagnetic wave is measured using an output port provided to the GTEM cell.

According to an aspect of one or more example embodiments, there is provided a GTEM cell including an outer conductor configured in a spherical shape; an input port through which an electrical signal is input; an inner conductor in which current flows in response to the electrical signal input through the input port in the outer conductor; a load resistance in which the current flowing in the inner conductor is terminated; an electromagnetic wave absorber provided to be adjacent to one surface of the load resistance and configured to absorb an electromagnetic wave formed by the current; and an output port configured as a coaxial transmission line and provided on a top surface of the outer conductor. A plurality of output ports may be present and an electrical signal for measuring intensity of an electric field in the GTEM cell may be output through the output port.

The outer conductor and the inner conductor may be provided in a structure in which a width of the inner conductor and the outer conductor adjacent to the load resistance is greater than that of the inner conductor and the outer conductor adjacent to the input port.

An opening for inserting a core of the coaxial transmission line that constitutes the output port may be formed on the top surface of the outer conductor.

The core of the coaxial transmission line may protrude vertically from an inner surface of the outer conductor and may be formed on the inner conductor.

The core of the coaxial transmission line may be formed between a test area within the GTEM and the electromagnetic wave absorber.

The electromagnetic wave may form a magnetic field in a direction parallel to the inner conductor by the current, and may form an electric field induced by the formed magnetic field in a direction vertical to the inner conductor.

The electric field may be coupled with a core of the coaxial transmission line parallel to a direction in which the electric field is formed by the magnetic field.

Intensity of the coupled electric field may be determined based on a length of the core of the coaxial transmission line that constitutes the output port, a location at which the core of the coaxial transmission line is placed in the outer conductor, and a thickness of the core of the coaxial transmission line.

Each of the plurality of output ports may be configured to measure a change in an electromagnetic field by a test object placed on a test area in the GTEM cell.

The GTEM cell may further include a power combiner configured to combine a power of a signal output through the output port based on intensity of the electromagnetic field measured at each of the plurality of output ports.

The GTEM cell may further include a capacitor formed between one surface of the core of the coaxial transmission line, which constitutes the output port, and the inner conductor.

According to another aspect of one or more example embodiments, there is provided a GTEM cell including an outer conductor configured in a spherical shape; an input port through which an electrical signal is input; an inner conductor in which current flows in response to the electrical signal input through the input port in the outer conductor; a load resistance in which the current flowing in the inner conductor is terminated; an electromagnetic wave absorber provided to be adjacent to one surface of the load resistance and configured to absorb an electromagnetic wave formed by the current; and an output port configured as a coaxial transmission line and provided on a top surface of the outer conductor. The output port may be connected to a microstrip line and an electrical signal for measuring intensity of an electric field in the GTEM cell may be output through the output port.

The microstrip line may be disposed in front of the output port in a direction in which the inner conductor is disposed, and connected to a core of the coaxial transmission line that constitutes the output port.

The inner conductor may be provided in a tapered shape based on return loss in the GTEM cell by the current flowing in the inner conductor.

The electromagnetic wave may form a magnetic field in a direction parallel to the inner conductor by the current, and may form an electric field induced by the formed magnetic field in a direction vertical to the inner conductor.

The magnetic field may be formed to be in parallel with the microstrip line disposed on the inner conductor and may be coupled with the microstrip line.

Intensity of the coupled magnetic field may be determined based on a distance between the microstrip line and the inner conductor and a width of the microstrip line.

A resistance element for termination may be disposed on one surface of the microstrip line that is not connected to a core of the coaxial transmission line.

The GTEM cell may further include a capacitor disposed to be in parallel with the microstrip line between the microstrip line and the output port.

According to another aspect of one or more example embodiments, there is provided an insertion loss measurement method performed at a GTEM cell, the method including measuring an attenuation amount by a conductivity of the GTEM cell in a state in which a test object is not placed on a test area, using a network analyzer connected to the GTEM cell; and measuring an insertion loss of the test object based on an attenuation amount by a conductivity of the GTEM cell in a state in which the test object is placed on the test area, using the network analyzer.

According to example embodiments, a GTEM cell may measure an insertion loss of a test object using an output port, which is provided to the GTEM as minimizing an effect against an electromagnetic field formed in the GTEM cell.

Also, according to example embodiments, a GTEM cell may measure an insertion loss of a test object using an output port provided with the GTEM cell after connecting a network analyzer to an input port and the output port.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates a structure of a gigahertz transverse electromagnetic (GTEM) cell for measuring an insertion loss of a test object according to an example embodiment;

FIG. 2 illustrates a structure of a GTEM cell for measuring an insertion loss based on an electric field coupling phenomenon according to an example embodiment;

FIG. 3 illustrates a structure of a GTEM cell for measuring an insertion loss based on a magnetic field coupling phenomenon according to an example embodiment;

FIG. 4 illustrates an example of an electromagnetic field formed in a GTEM cell according to an example embodiment; and

FIG. 5 is a flowchart illustrating a method of measuring an insertion loss of a test object using a GTEM cell according to an example embodiment.

### DETAILED DESCRIPTION

Hereinafter, some example embodiments will be described in detail with reference to the accompanying drawings. Regarding the reference numerals assigned to the elements in the drawings, it should be noted that the same elements will be designated by the same reference numerals, wherever possible, even though they are shown in different drawings. Also, in the description of embodiments, detailed description of well-known related structures or functions will be omitted when it is deemed that such description will cause ambiguous interpretation of the present disclosure.

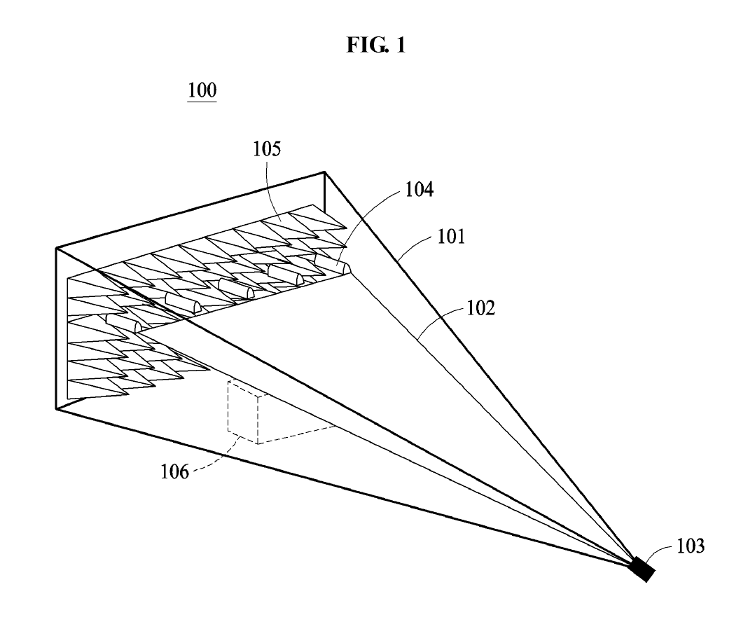

FIG. 1 illustrates a structure of a gigahertz transverse electromagnetic (GTEM) cell for measuring an insertion loss of a test object according to an example embodiment.

Referring to FIG. 1, a GTEM cell 100 is provided in a spherical coaxial transmission line shape, and may include an outer conductor 101, an inner conductor 102, an input port 103, a load resistance 104, an electromagnetic wave absorber 105, a test area 106, and an output port. Similar to a transverse electromagnetic (TEM) cell, the GTEM cell 100 may be configured as a spherical transmission line. Accordingly, the GTEM cell 100 may be provided in a structure in which a width of the inner conductor 102 and the outer conductor 101 becomes narrower with getting along a way from the input port 103 toward the load resistance 104.

An electrical signal may be input through the input port 103. The inner conductor 102 may be provided in the outer conductor 101 and current may flow in the inner conductor 102 in response to an electrical signal input through the input port 103. The load resistance 104 may terminate the current transmitted through the inner conductor 102. Here, the GTEM cell 100 may determine a resistance value of the load resistance 104 at a design point of the GTEM cell 100. A predetermined resistance value may be determined to minimize a return loss of current occurring due to a difference between characteristic impedance of the inner conductor 102 and the load resistance 104.

The electromagnetic wave absorber 105 is provided to be adjacent to one surface of the load resistance 104, and may absorb an electromagnetic wave formed in the GTEM cell 100 to remove a reflection phenomenon by the current. The electromagnetic wave absorber 105 may absorb the electromagnetic field reaching the load resistance 104 and accordingly, may minimize a return loss of the electromagnetic field.

Here, due to the termination between the current and the electromagnetic field, the GTEM cell 100 is provided in a shape of a coaxial transmission line and one surface of the GTEM cell 100 is open, which means that the corresponding surface does not cause any reflection of the current and the electromagnetic field. The return loss of the electromagnetic field may be measured by providing the output port on a top surface or a surface of the outer conductor 101.

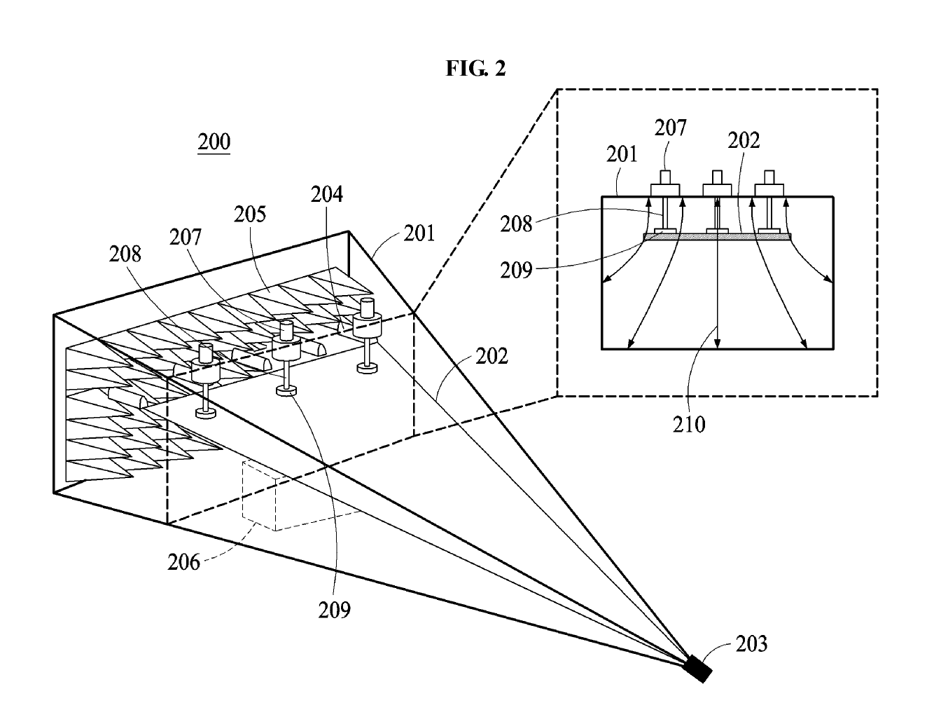

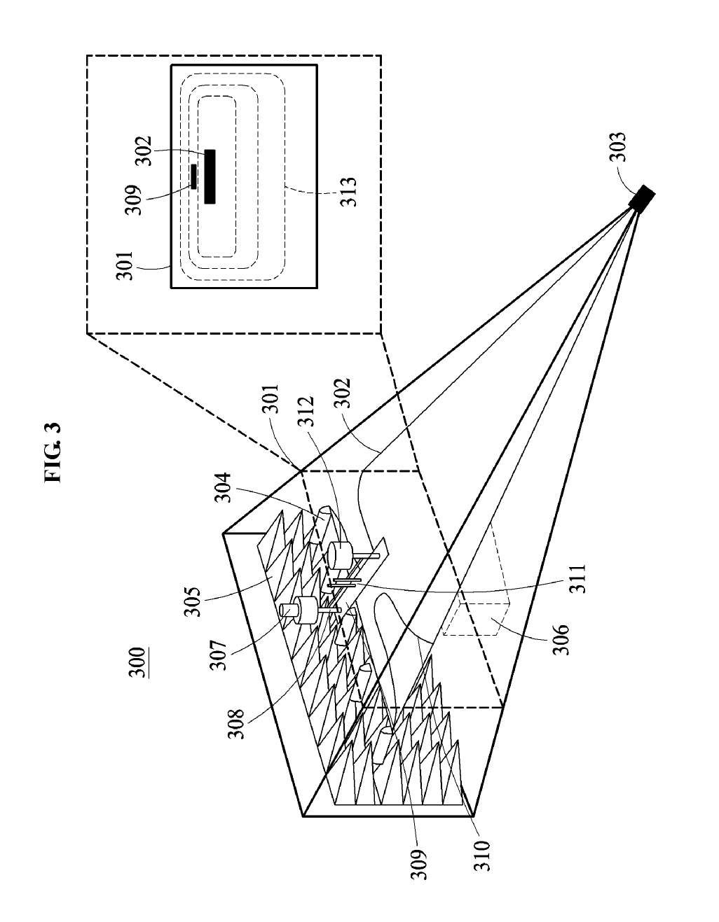

The output port may be configured as a coaxial transmission line. In detail, the output port may form an opening on the outer conductor 101 to insert a core of the coaxial transmission line. Here, a diameter of the opening may be determined based on a diameter of the core of the coaxial transmission line not to affect the electromagnetic field formed in the GTEM cell 100. The core of the coaxial transmission line may be inserted into the GTEM cell 100 through the opening formed on the outer conductor 101, and may be formed up to the surface of the inner conductor 102. A structure of the core of the coaxial transmission line will be further described with reference to FIGS. 2 and 3.

The GTEM cell 100 may measure an insertion loss of a test object from the GTEM cell 100 through the output port disposed on the surface of the GTEM cell 100 and connected to the core of the coaxial transmission line.

FIG. 2 illustrates a structure of a GTEM cell for measuring an insertion loss based on an electric field coupling phenomenon according to an example embodiment.

Referring to FIG. 2, a GTEM cell 200 may include an output port 207 and may measure an insertion loss of a test object. In detail, the GTEM cell 200 may include an outer conductor 201, an inner conductor 202, an input port 203, a load resistance 204, and an electromagnetic wave absorber 205.

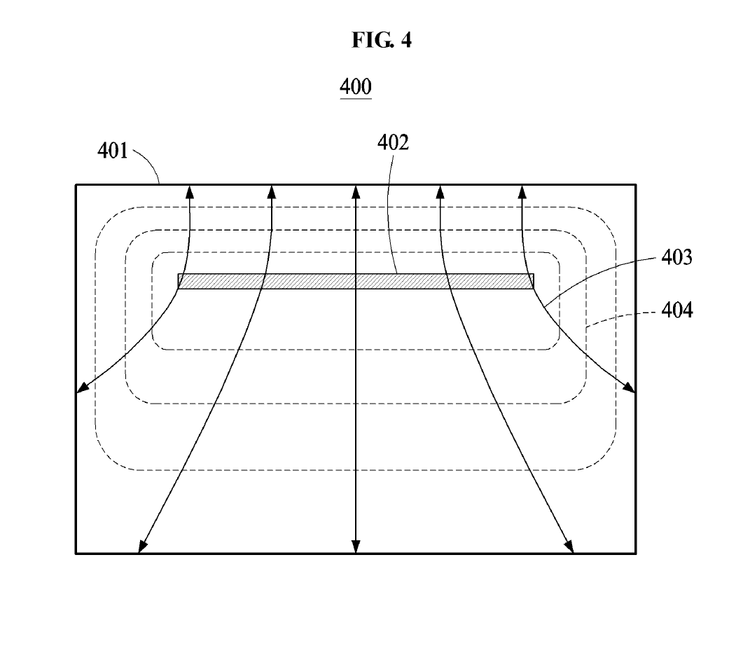

Once a signal is input through the input port 203, an electromagnetic field having uniform intensity corresponding to current by the signal may be formed. A form of the electromagnetic field being formed will be further described with reference to FIG. 4.

The output port 207 may be provided to the outer conductor 201 to measure a change in intensity of the electromagnetic field occurring due to the test object placed on a test area 206. The output port 207 may be disposed on the outer conductor 201 and may be configured as a coaxial transmission line. A core 208 of the coaxial transmission line that constitutes the output port 207 may protrude vertically from an inner side of the outer conductor 201 and may be formed up to the surface of the inner conductor 202.

The GTEM cell 200 may measure an insertion loss using an electric field 210 formed above the inner conductor 202 in the electromagnetic field that is formed inside the GTEM cell 200 in response to the signal input through the input port 203. That is, the electric field 210 formed above the inner conductor 202 is formed to be in parallel with the core 208 of the coaxial transmission line that constitutes the output port 207. Accordingly, an electric field coupling phenomenon that the electric field 210 couples with the core 208 of the coaxial transmission line may occur.

Thus, a signal having a power proportional to intensity of the electric field 210 formed in the GTEM cell 200 may be output through the output port 207. Here, a proportional ratio between the intensity of the electric field 210 and the power may be determined based on a length of the core 208 of the coaxial transmission line, a location at which the core 208 of the coaxial transmission line is placed in the GTEM cell 200, and a thickness of the core 208 of the coaxial transmission line. The GTEM cell 200 may measure the power of the signal output through the output port 207 and may measure the intensity of the electric field 210 formed in the GTEM cell 200.

Here, an insertion loss may occur in the GTEM cell 200 due to the test object placed on the test area 206. If the insertion loss occurs, the power of the signal output through the output port 207 may vary based on how much the insertion loss has occurred by the test object has occurred, and the insertion loss by the test object may be measured by measuring a variation of the power.

In the related art, due to the output port 207 provided to measure the insertion loss by the test object according to the electromagnetic field formed in the GTEM cell 200, the uniformity of the electromagnetic field on the test area 206 may be degraded. However, according to example embodiments, the GTEM cell 200 may prevent the degradation in the uniformity of the electromagnetic field on the test area 206 using the output port 207.

In the GTEM cell 200, a structure, that is, the core 208 of the coaxial transmission line, may use a relatively small space. In detail, an opening may be formed on the outer conductor 201 to insert the core 208 of the coaxial transmission line that constitutes the output port 207. Since the core 208 of the coaxial transmission line has a very small diameter, the opening formed on the outer conductor 201 may be formed to have a very small diameter based on the diameter of the core 208 of the coaxial transmission line in order not to affect the electromagnetic field formed in the GTEM cell 200.

Also, a power coupling may occur during a coupling process between the electric field 210 and the core 208 of the coaxial transmission line that constitutes the output port 207. Accordingly, the output port 207 may be designed to significantly decrease a ratio between the power of the electromagnetic field formed in the GTEM cell 200 and transmitted from the inner conductor 202 and the power of the signal output through the output port 207. The GTEM cell 200 may minimize the effect against the electromagnetic field in the GTEM cell 200 by determining a power ratio of the output port 207 to be relatively low during a design process. For example, the GTEM cell 200 may minimize the effect against the electromagnetic field in the GTEM cell 200 by determining the power ratio of the output port 207 to be 20 dB or less.

Also, if the power coupling occurring during the coupling process between the electric field 210 and the core 208 of the coaxial transmission line is relatively low, the power of the signal output through the output port 207 may decrease, which may lead to making it impossible to measure the insertion loss. According to example embodiments, it is possible to increase a power of a signal associated with the output port 207 to be measured by providing a plurality of output ports 207 on the outer conductor 201 and by combining powers of signals output from the respective output ports 207. A power combiner may be used to combine the powers of the signals output from the respective output ports 207.

The GTEM cell 200 may decrease the effect of the output port 207 against the electromagnetic field formed in GTEM cell 200 by designing the opening formed on the outer conductor 201 for the core 208 of the coaxial transmission line constituting the output port 207 to have a relatively small diameter and by designing the power coupling to be small. Also, the GTEM cell 200 may additionally adjust a location of the core 208 of the coaxial transmission line constituting the output port 207 to decrease the effect of the output port 207 against the electromagnetic field formed in the GTEM cell 200. To this end, the GTEM cell 200 may provide the core 208 of the coaxial transmission line between the test area 206 and the electromagnetic wave absorber 205.

In detail, the electromagnetic field formed above the inner conductor 202 by the signal input through the input port 203 may flow from the input port 203 toward the electromagnetic wave absorber 205. The core 208 of the coaxial transmission line may be provided between the test area 206 and the electromagnetic wave absorber 205, and may pass the test area 206 and then be coupled with the electric field 210. Although the core 208 of the coaxial transmission line 207 affects the electromagnetic field formed in the GTEM cell 200, the core 208 of the coaxial transmission line may be provided behind the test area 206 and thus, may affect the electromagnetic field after passing through the test area 206. That is, the electromagnetic field on the test area 206 may not be affected by the core 208 of the coaxial transmission line.

In the GTEM cell 200, a measurement device, such as a network analyzer, may be connected to the output port 207 to measure the power of the signal output through the output port 207. Also, if a plurality of output ports 207 is present, the power combiner may be connected to the respective output ports 207 to couple powers of signals output from the respective output ports 207. In this case, a return loss occurring due to a connection between the measurement device or the power combiner and the output port 207 may need to be minimized. Accordingly, an impedance matching condition between the output port 207 and the measurement device or the power combiner needs to be formed.

To satisfy the impedance matching condition, a capacitor 209 may be provided between an end of the core 208 of the coaxial transmission line and the surface of the inner conductor 202. The capacitor 209 may offset an inductance component of the core 208 of the coaxial transmission line and may remove a reactive component of impedance of the output port 207. Through this, it is possible to perform impedance matching between the measurement device or the power combiner and the output port 207, and to minimize the return loss.

FIG. 3 illustrates a structure of a GTEM cell for measuring an insertion loss based on a magnetic field coupling phenomenon according to an example embodiment.

Referring to FIG. 3, a GTEM cell 300 may include an output port 307 and may measure an insertion loss of a test object. In detail, the GTEM cell 300 may include an outer conductor 301, an inner conductor 302, an input port 303, a load resistance 304, and an electromagnetic wave absorber 305.

Here, a microstrip line 309 may be connected to a core 308 of a coaxial transmission line constituting an output port 307. The microstrip line 309 may be disposed on one surface of or above the inner conductor 302, and may be positioned in a direction from the electromagnetic wave absorber 305 in the GTEM cell 300 toward the input port 303. The GTEM cell 200 may measure an insertion loss using a magnetic field 313 formed above the inner conductor 302 among magnetic fields 313 formed in the GTEM cell 300. That is, the magnetic field 313 formed above the inner conductor 302 may be formed to be in parallel with a wide surface of the microstrip line 309 and a magnetic field coupling phenomenon that the magnetic field 313 couples with the microstrip line 309 may occur.

Similar to the example embodiment of FIG. 2, a signal having a power proportional to intensity of the magnetic field 313 in the GTEM cell 300 may be output through the output port 307. Here, a proportional ratio between the intensity of the magnetic field 313 and the power may be determined based on a distance between the microstrip line 309 and the inner conductor 302 and a width of the microstrip line 309. The GTEM cell 300 may measure the power of the signal output from the output port 307 and may measure the intensity of the magnetic field 313 formed in the GTEM cell 300.

Here, an insertion loss may occur in the GTEM cell 300 due to the test object placed on a test area 306. If the insertion loss occurs, the power of the signal output through the output port 307 may vary based on how much the insertion loss has occurred by the test object, and the insertion loss by the test object may be measured by measuring a variation of the power.

As described above with FIG. 2, the output port 307 may degrade a uniformity of an electromagnetic field of the test area 306. By designing the output port 307 so that a power coupling occurring when coupling the microstrip line 309 and the magnetic field 313 is 20 dB or less, it is possible to minimize the effect of the microstrip line 309 against the electromagnetic field in the GTEM cell 300.

Also, if a power coupling between the microstrip line 309 and the magnetic field 313 is relatively low, the power of the signal output through the output port 307 may decrease, which may lead to making it impossible to measure the insertion loss. Accordingly, it is possible to partially reduce a width of the inner conductor 302 in which the microstrip line 309 couples with the magnetic field 313.

According to a reduction in the width of the inner conductor 302, density of current flowing in the inner conductor 302 may increase and the power coupling may increase. According to the reduction in the width of the inner conductor 302, impedance of the inner conductor 302 may significantly vary and accordingly, the current flowing in the inner conductor 302 may experience a return loss.

To minimize the return loss, the inner conductor 302 may be used in a tapered shape in which the width of the inner conductor 302 becomes narrower and then wider with getting along a way from the input port 303 toward the electromagnetic wave absorber 305. That is, the inner conductor 302 may be designed in the tapered shape to prevent a sudden impedance change in a section in which the width of the inner conductor 302 becomes narrow or wide. As described above with FIG. 2, the microstrip line 309 may be provided behind the test area 306 and thus, may not affect the electromagnetic field on the test area 306.

Since a measurement device is connected to the output port 307, an impedance matching condition needs to be formed between the measurement device and the output port 307 to minimize a return loss. To this end, another end of the microstrip line 309 may be terminated at a resistance element 312. The impedance of the output port 307 may be adjusted by adjusting a resistance value of the resistance element 312.

A capacitor 311 disposed in parallel with the microstrip line 309 may be used together with the resistance element 312. The capacitor 311 may offset an inductance component of the microstrip line 309 and may remove a reactive component of impedance of the output port 307. Through this, it is possible to perform impedance matching and to minimize the return loss by adjusting the impedance of the output port 307 and by removing the reactive component.

FIG. 4 illustrates an example of an electromagnetic field formed in a GTEM cell according to an example embodiment.

Referring to FIG. 4, in a GTEM cell 400, a signal may be input through an input port, and current by the signal input through the input port may flow in an inner conductor 402 of the GTEM cell 400. In the GTEM cell 400, an electromagnetic field may be formed around the inner conductor 402 by the current flowing in the inner conductor 402.

That is, a magnetic field 404 may be formed in parallel with the inner conductor 402. The magnetic field 404 formed in parallel with the inner conductor 402 may induce an electric field 403. The induced electric field 403 may be formed in a direction vertical to the inner conductor 402.

Also, due to a TEM mode in which the electric field 403 and the magnetic field 404 are orthogonal to each other, the electromagnetic field may have a property of a travelling wave that is transmitted from the input port toward a load resistance along the inner conductor 402.

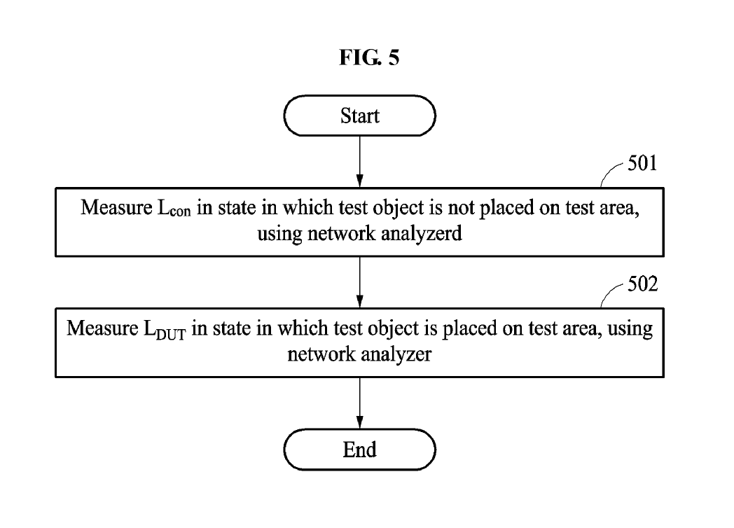

FIG. 5 is a flowchart illustrating a method of measuring an insertion loss of a test object using a GTEM cell according to an example embodiment.

An insertion loss of a test object may be measured based on the structure of FIGS. 2 and 3. In detail, a plurality of output ports may be disposed on an outer conductor of a GTEM cell. A power combiner may be used to combine powers of signals output from the plurality of output ports formed on the GTEM cell. Here, a network analyzer may be connected to the output port of the power combiner. That is, the network analyzer may be connected to the GTEM cell. Here, the network analyzer may include two ports, and the two ports may be connected to the input port and the output port of the GTEM cell, respectively.

In operation 501, the GTEM cell may measure L_{con} in a state in which the test object is not placed on a test area, using the network analyzer.

That is, in a state in which the test object is not placed on the test area, the GTEM cell may measure parameter S using the network analyzer and may input S₁₁ and S₂₁ among the measured parameters S to Equation 1.

10 log₁₀(1−10^{S}^{₁₁}^{/10})−|L_{con}|=S₂₁+C_{coupling} [Equation 1]

In Equation 1, C_{coupling} denotes a power coupling. The power coupling may be acquired prior to measuring the parameter S according to a theoretical equation about an electromagnetic field in the GTEM cell or a numerical analysis about the GTEM cell. Also, L_{con}, as a variable denoting a conductive loss of the GTEM cell, may represent an attenuation amount by a conductivity of an inner conductor and an outer conductor during a process in which the electromagnetic field formed through the input port and transmitted to the output port.

Any variable used in Equation 1 may have a unit of dB. L_{con} may be acquired from Equation 1.

In operation 502, the GTEM cell may measure the insertion loss of the test object in a state in which the test object is placed on the test area, using the network analyzer.

That is, in a state in which the test object is placed on the test area, the GTEM may measure S₁₁ and S₂₁ using the network analyzer and may input the measured Sᵢᵢ and S₂₁ to Equation 2.

10 log₁₀(1−10^{S}^{₁₁}^{/10})−|L_{con}|−L_{DUT}|=S₂₁+C_{coupling} [Equation 1]

In Equation 2, L_{DUT} denotes the insertion loss of the test object. Regardless of whether the test object is present, C_{coupling} is identical and thus, L_{DUT} may be acquired by applying the measured S₁₁ and S₂₁ and L_{con} of Equation 1 to Equation 2. Any variable used in Equation 2 may have a unit of dB.

The components described in the example embodiments may be achieved by hardware components including at least one DSP (Digital Signal Processor, a processor, a controller, an Application Specific Integrated Circuit (ASIC), a programmable logic element such as a Field Programmable Gate Array (FPGA), other electronic devices, and combinations thereof. At least some of the functions or the processes described in the example embodiments may be achieved by software, and the software may be recorded on a recording medium. The components, the functions, and the processes described in the example embodiments may be achieved by a combination of hardware and software.

The processing device described herein may be implemented using hardware components, software components, and/or a combination thereof. For example, the processing device and the component described herein may be implemented using one or more general-purpose or special purpose computers, such as, for example, a processor, a controller and an arithmetic logic unit (ALU), a digital signal processor, a microcomputer, a field programmable gate array (FPGA), a programmable logic unit (PLU), a microprocessor, or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will be appreciated that a processing device may include multiple processing elements and/or multiple types of processing elements. For example, a processing device may include multiple processors or a processor and a controller. In addition, different processing configurations are possible, such as parallel processors.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM, random access memory (RAM, flash memory (e.g., USB flash drives, memory cards, memory sticks, etc., and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A gigahertz transverse electromagnetic (GTEM) cell comprising:
an outer conductor configured in a spherical shape;
an input port through which an electrical signal is input;
an inner conductor in which current flows in response to the electrical signal input through the input port in the outer conductor;
a load resistance in which the current flowing in the inner conductor is terminated;
an electromagnetic wave absorber provided to be adjacent to one surface of the load resistance and configured to absorb an electromagnetic wave formed by the current; and
an output port configured as a coaxial transmission line and provided on a top surface of the outer conductor,
wherein a plurality of output ports are present and an electrical signal for measuring intensity of an electric field in the GTEM cell is output through the output port.

2. The GTEM cell of claim 1, wherein the outer conductor and the inner conductor are provided in a structure in which a width of the inner conductor and the outer conductor adjacent to the load resistance is greater than that of the inner conductor and the outer conductor adjacent to the input port.

3. The GTEM cell of claim 1, wherein an opening for inserting a core of the coaxial transmission line that constitutes the output port is formed on the top surface of the outer conductor.

4. The GTEM cell of claim 3, wherein the core of the coaxial transmission line protrudes vertically from an inner surface of the outer conductor and is formed on the inner conductor.

5. The GTEM cell of claim 3, wherein the core of the coaxial transmission line is formed between a test area within the GTEM and the electromagnetic wave absorber.

6. The GTEM cell of claim 1, wherein the electromagnetic wave forms a magnetic field in a direction parallel to the inner conductor by the current, and forms an electric field induced by the formed magnetic field in a direction vertical to the inner conductor.

7. The GTEM cell of claim 6, wherein the electric field is coupled with a core of the coaxial transmission line parallel to a direction in which the electric field is formed by the magnetic field.

8. The GTEM cell of claim 7, wherein intensity of the coupled electric field is determined based on a length of the core of the coaxial transmission line that constitutes the output port, a location at which the core of the coaxial transmission line is placed in the outer conductor, and a thickness of the core of the coaxial transmission line.

9. The GTEM cell of claim 1, wherein each of the plurality of output ports is configured to measure a change in an electromagnetic field by a test object placed on a test area in the GTEM cell.

10. The GTEM cell of claim 9, further comprising:
a power combiner configured to combine a power of a signal output through the output port based on intensity of the electromagnetic field measured at each of the plurality of output ports.

11. The GTEM cell of claim 1, further comprising:
a capacitor formed between one surface of the core of the coaxial transmission line that constitutes the output port and the inner conductor.

12. A gigahertz transverse electromagnetic (GTEM) cell comprising:
an outer conductor configured in a spherical shape;
an input port through which an electrical signal is input;
an inner conductor in which current flows in response to the electrical signal input through the input port in the outer conductor;
a load resistance in which the current flowing in the inner conductor is terminated;
an electromagnetic wave absorber provided to be adjacent to one surface of the load resistance and configured to absorb an electromagnetic wave formed by the current; and
an output port configured as a coaxial transmission line and provided on a top surface of the outer conductor,
wherein the output port is connected to a microstrip line and an electrical signal for measuring intensity of an electric field in the GTEM cell is output through the output port.

13. The GTEM cell of claim 12, wherein the microstrip line is disposed in front of the output port in a direction in which the inner conductor is disposed, and connected to a core of the coaxial transmission line that constitutes the output port.

14. The GTEM cell of claim 12, wherein the inner conductor is provided in a tapered shape based on return loss in the GTEM cell by the current flowing in the inner conductor.

15. The GTEM cell of claim 12, wherein the electromagnetic wave forms a magnetic field in a direction parallel to the inner conductor by the current, and forms an electric field induced by the formed magnetic field in a direction vertical to the inner conductor.

16. The GTEM cell of claim 15, wherein the magnetic field is formed to be in parallel with the microstrip line disposed on the inner conductor and is coupled with the microstrip line.

17. The GTEM cell of claim 16, wherein intensity of the coupled magnetic field is determined based on a distance between the microstrip line and the inner conductor and a width of the microstrip line.

18. The GTEM cell of claim 12, wherein a resistance element for termination is disposed on one surface of the microstrip line that is not connected to a core of the coaxial transmission line.

19. The GTEM cell of claim 13, further comprising:
a capacitor disposed to be in parallel with the microstrip line between the microstrip line and the output port.

20. An insertion loss measurement method performed at a gigahertz transverse electromagnetic (GTEM) cell, the method comprising:
measuring an attenuation amount by a conductivity of the GTEM cell in a state in which a test object is not placed on a test area, using a network analyzer connected to the GTEM cell; and
measuring an insertion loss of the test object based on an attenuation amount by a conductivity of the GTEM cell in a state in which the test object is placed on the test area, using the network analyzer.
